(19) United States
(12) Patent Application Publication
(10) Pub. No.: US 2013/0069123 A1
(43) Pub. Date: Mar. 21, 2013

(54) CMOS SEMICONDUCTOR DEVICES HAVING STRESSOR REGIONS AND RELATED FABRICATION METHODS

(71) Applicants: Ralf Illgen, Dresden (DE); Stefan Flachowsky, Dresden (DE); Ina Ostermay, Berlin (DE)

(72) Inventors: Ralf Illgen, Dresden (DE); Stefan Flachowsky, Dresden (DE); Ina Ostermay, Berlin (DE)

(73) Assignee: GLOBALFOUNDRIES INC., Grand Cayman (KY)

(21) Appl. No.: 13/235,173

(22) Filed: Sep. 16, 2011

(51) Int. Cl. H01L 21/8238; H01L 29/78

(52) U.S. Cl. 257/288; 438/199; 257/E29.255; 257/E21.634

(57) ABSTRACT

Semiconductor devices and related fabrication methods are provided. An exemplary fabrication method involves forming first doped stressor regions in a first region of semiconductor material, forming second doped stressor regions in a second region of semiconductor material after forming the first doped stressor regions, and after forming the second doped stressor regions, annealing the semiconductor device structure to activate ions of the first and second doped stressor regions concurrently. The amount of time for the annealing is chosen to inhibit diffusion of the ions of the first and second doped stressor regions.

### TECHNICAL FIELD

Embodiments of the subject matter generally relate to semiconductor device structures and related fabrication methods, and more particularly, embodiments of the subject matter relate to devices and related fabrication methods for CMOS semiconductor devices having epitaxial stressor regions.

### BACKGROUND

Transistors, such as metal oxide semiconductor field-effect transistors (MOSFETs), are the core building block of the vast majority of semiconductor devices. Epitaxial stressor regions are frequently used to increase the mobility of carriers in the channels of the MOS transistors, and thereby achieve a corresponding improvement in performance. However, different types of stressor regions have different chemical properties that increase the difficulty of integrating epitaxial stressor regions for both PMOS devices and NMOS devices into existing CMOS fabrication processes.

### BRIEF SUMMARY

A method is provided for fabricating a semiconductor device structure. The method involves forming first doped stressor regions in a first region of semiconductor material, forming second doped stressor regions in a second region of semiconductor material after forming the first doped stressor regions, and after forming the second doped stressor regions, annealing the semiconductor device structure to activate ions of the first and second doped stressor regions concurrently. The amount of time for the annealing is chosen to inhibit diffusion of the ions of the first and second doped stressor regions.

In another embodiment, a method of fabricating a semiconductor device structure on a semiconductor substrate including a first region of semiconductor material and a second region of semiconductor material involves the steps of epitaxially growing in-situ doped silicon germanium regions in the first region of semiconductor material, epitaxially growing in-situ doped silicon carbon regions in the second region of semiconductor material prior to activating ions of the silicon germanium regions, and performing a diffusionless anneal to concurrently activate ions in the silicon carbon regions and the ions in the silicon germanium regions.

In another embodiment, an exemplary semiconductor device structures is provided. The semiconductor device includes a semiconductor material, a gate structure overlying the semiconductor material, in-situ doped stressor regions formed in the semiconductor material about the gate structure, and in-situ doped silicon material overlying the in-situ doped stressor regions.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIGS. 1-8 are cross-sectional views that illustrate a semiconductor device structure and methods for fabricating the semiconductor device structure in exemplary embodiments.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

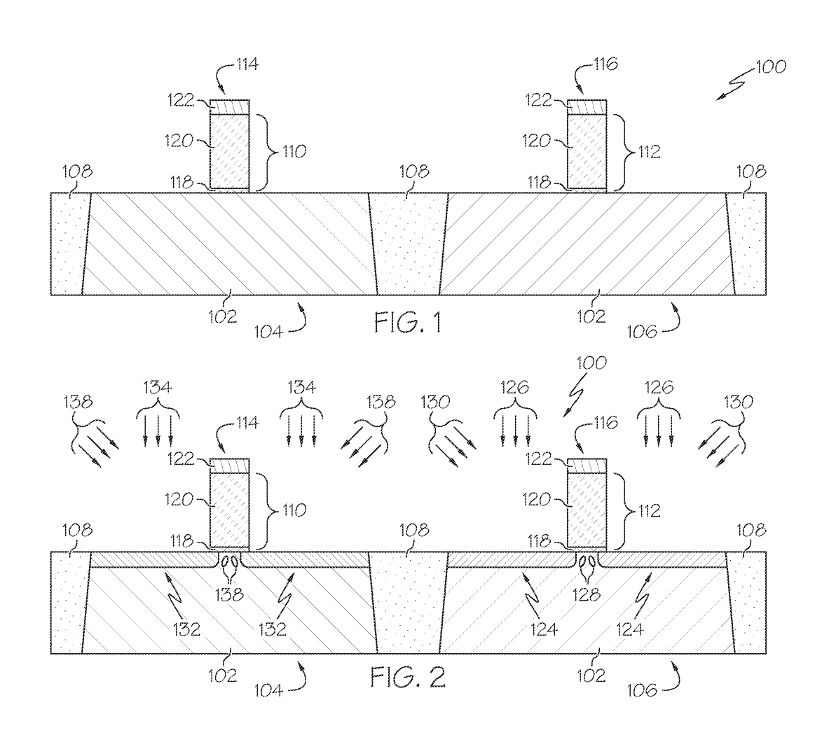

FIGS. 1-8 illustrate, in cross-section, a CMOS semiconductor device structure 100 and related process steps for fabricating the CMOS semiconductor device structure 100. As described in greater detail below, the fabricated CMOS semiconductor device structure 100 includes in-situ doped epitaxially-grown stressor regions that increase mobility of carriers in the channel regions of both N-type and P-type transistor devices. Although the subject matter is described herein in the context of a CMOS semiconductor device, the subject matter is not intended to be limited to CMOS semiconductor devices, and may be utilized with other MOS semiconductor devices which are not CMOS semiconductor devices. Additionally, although the term “MOS device” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate. Various steps in the fabrication of MOS semiconductor devices are well known and so, in the interest of brevity, many conventional steps will only be mentioned briefly herein or will be omitted entirely without providing the well known process details.

Turning now to FIG. 1, in an exemplary embodiment, the fabrication process begins by forming gate structures 110, 112 having oxide gate caps 114, 116 overlying isolated regions 104, 106 of semiconductor material 102. The isolated regions 104, 106 are preferably formed from a substrate (or wafer) of semiconductor material 102 (e.g., a silicon-on-insulator (SOI) substrate or a bulk silicon substrate). The semiconductor material 102 is preferably a silicon material, wherein the term “silicon material” is used herein to encompass the relatively pure silicon materials typically used in the semiconductor industry as well as silicon admixed with other elements. Alternatively, the semiconductor material 102 can be realized as germanium, gallium arsenide, and the like, or the semiconductor material 102 can include layers of different semiconductor materials. For convenience, but without limitation, the semiconductor material 102 may hereinafter be referred to as a silicon material. The regions 104, 106 are electrically isolated from neighboring regions of the substrate by performing shallow trench isolation (STI) or another isolation process to form an insulating material 108, such as silicon dioxide, in between the regions 104, 106 of the silicon material 102. For convenience, but without limitation, the insulating material 108 may hereinafter be referred to as the field oxide.

Prior to forming gate structures 110, 112, the isolated regions 104, 106 are doped in a conventional manner to achieve a desired dopant profile for the body regions (or well regions) of the subsequently formed transistor structures. For example, an N-type region 106 of semiconductor material 102 may be formed by masking region 104 and implanting N-type ions, such as phosphorous or arsenic ions, into region 106. In this regard, the N-type region 106 functions as an N-well for a PMOS transistor structure subsequently formed on region 106. In a similar manner, the N-type region 106 is masked and a P-well for a subsequently formed NMOS transistor structure is formed in region 104 by implanting P-type ions, such as boron ions, into region 104. For convenience, the N-type (or N-well) region 106 may alternatively be referred to herein as the PMOS transistor region and the P-type (or P-well) region 104 may alternatively be referred to herein as the NMOS transistor region.

After doping the isolated regions 104, 106, the fabrication process continues by forming the gate structures 110, 112 overlying the isolated regions 104, 106. The gate structures 110, 112 function as gate electrodes for the MOS transistor structures subsequently formed on the regions 104, 106 of silicon material 102 and the gate structures 110, 112 can be created using a conventional gate stack module or any combination of well-known process steps. As illustrated in FIG. 1, the gate structures 110, 112 preferably include at least one layer of dielectric material 118 and at least one layer of conductive gate electrode material 120. For example, the gate structure 110, 112 may be formed by growing or depositing one or more layers of dielectric material 118, such as an oxide material or a high-k dielectric material, overlying the silicon material 102. After forming the gate dielectric material 118, fabrication of gate structures 110, 112 continues by depositing one or more layers of conductive gate electrode material 120, such as a metal material or polycrystalline silicon (polysilicon), overlying the layer(s) of dielectric material 118. It should be understood that various numbers, combinations and/or arrangements of materials may be utilized for the gate structure in a practical embodiment, and the subject matter described herein is not limited to any particular number, combination, or arrangement of gate material(s) in the gate structure. In an exemplary embodiment, the uppermost portion of the gate electrode material 120 is realized as polysilicon to facilitate formation of silicide contact regions on the upper surfaces of the gate structures 110, 112, as described below in the context of FIG. 8.

In the illustrated embodiment, after forming the gate electrode material 120, fabrication of the semiconductor device structure 100 continues by depositing a layer of oxide material 122 overlying the conductive gate electrode material 120. In an exemplary embodiment, a layer of silicon dioxide 122 is conformably deposited overlying the conductive material to a thickness in the range of about 3 nm to about 5 nm by plasma enhanced chemical vapor deposition (PECVD). After the oxide material 122 is formed, portions of the dielectric material 118, conductive gate electrode material 120, and oxide capping material 122 are then selectively removed using an anisotropic etchant and a corresponding etch mask to define gate structures 110, 112 with sidewalls substantially perpendicular to (or orthogonal to) the surface of the silicon material 102 and oxide gate caps 114, 116 overlying the gate structures 110, 112. As described in greater detail below, the oxide gate caps 114, 116 protect the underlying gate materials 118, 120 during subsequent process steps. In this regard, it should be noted that in some embodiments, the gate electrode material 120 may be doped prior to forming the oxide material 122.

Referring now to FIG. 2, in an exemplary embodiment, fabrication of the semiconductor device structure 100 continues by forming source and drain extension regions and halo regions within the isolated regions 104, 106 of silicon material 102. For example, P-type source and drain extension regions 124 may be formed in the N-well region 106 by masking the NMOS transistor region 104 (e.g., using photoresist or another masking material) and implanting P-type ions (illustrated by arrows 126), such as boron ions, into the exposed silicon material 102 of the PMOS transistor region 106 to a desired depth and/or sheet resistivity using the gate structure 112 and/or oxide gate cap 116 as an implantation mask. In an exemplary embodiment, the source/drain extension regions 124 are relatively shallow and have a junction depth of about 10 nm to about 20 nm and have a peak dopant concentration in the range of about 1×10²⁰/cm³ to about 5×10²⁰/cm³. However, it will be appreciated that the junction depth and/or resistivity of the source/drain extension regions will vary depending on the needs of the particular device. Also, while the NMOS transistor region 104 is masked, N-type halo regions 128 are formed in the channel region underlying the gate structure 112 by implanting N-type ions (illustrated by arrows 130), such as phosphorous ions or arsenic ions, at an angle to the surface of the silicon material 102 using the gate structure 112 and/or oxide gate cap 116 as an implantation mask.

Prior to activating the dopant ions of the P-type source/drain extensions 124 and the N-type halo regions 128, the NMOS transistor region 104 is unmasked while the PMOS transistor region 106 is masked and N-type source/drain extension regions 132 and P-type halo regions 136 are formed in the P-well region 104. In a similar manner as described above, the N-type extension regions 132 are formed by implanting N-type ions (illustrated by arrows 134), such as phosphorous or arsenic ions, into the exposed silicon material 102 of the NMOS transistor region 104 and the P-type halo regions 136 are formed by implanting P-type ions (illustrated by arrows 138), such as boron ions, at an angle to the surface of the silicon material 102 using the gate structure 110 and/or oxide gate cap 114 as an implantation mask. After the N-type source/drain extensions 132 and P-type halo regions 136 are formed in the P-well region 104, the PMOS transistor region 106 is unmasked, resulting in the semiconductor device structure 100 illustrated in FIG. 2.

Still referring to FIG. 2, in an exemplary embodiment, after forming the source/drain extensions 124, 132 and halo regions 128, 136 in both transistor regions 104, 106, a diffusionless annealing (or ultrafast annealing (UFA)) is performed for a high degree of dopant activation as well as to re-crystallize the substrate silicon material 102 and remedy any lattice defects that may be caused by the ion implantation process steps without causing diffusion of the implanted dopant ions. In this regard, the semiconductor device structure 100 of FIG. 2 is heated (e.g., by performing a flash anneal or a laser anneal) for an amount of time that is less than a threshold amount of time that would otherwise result in the diffusion of the dopant ions in the source/drain extensions 124, 132 and/or halo regions 128, 136. In an exemplary embodiment, the semiconductor device structure 100 is heated to a temperature of about 1200° C. or more for about 10 milliseconds or less to inhibit diffusion of dopant ions in the source/drain extensions 124, 132 and/or halo regions 128, 136 or otherwise ensure that any diffusion of dopant ions in the source/drain extensions 124, 132 and/or halo regions 128, 136 is negligible. The relatively high temperature of the diffusionless anneal activates the dopant ions of the source/drain extensions 124, 132 and/or halo regions 128, 136 but the duration of the diffusionless anneal is such that any lateral diffusion of the dopant ions is inhibited or otherwise prevented. It should be noted that due to the diffusionless annealing processes described herein, in exemplary embodiments, the source/drain extensions 124, 132 are formed by ion implantation using only the gate structures and/or gate caps as ion implantation masks and without the use of any offset spacer(s) to define the lateral extent of the source/drain extension regions.

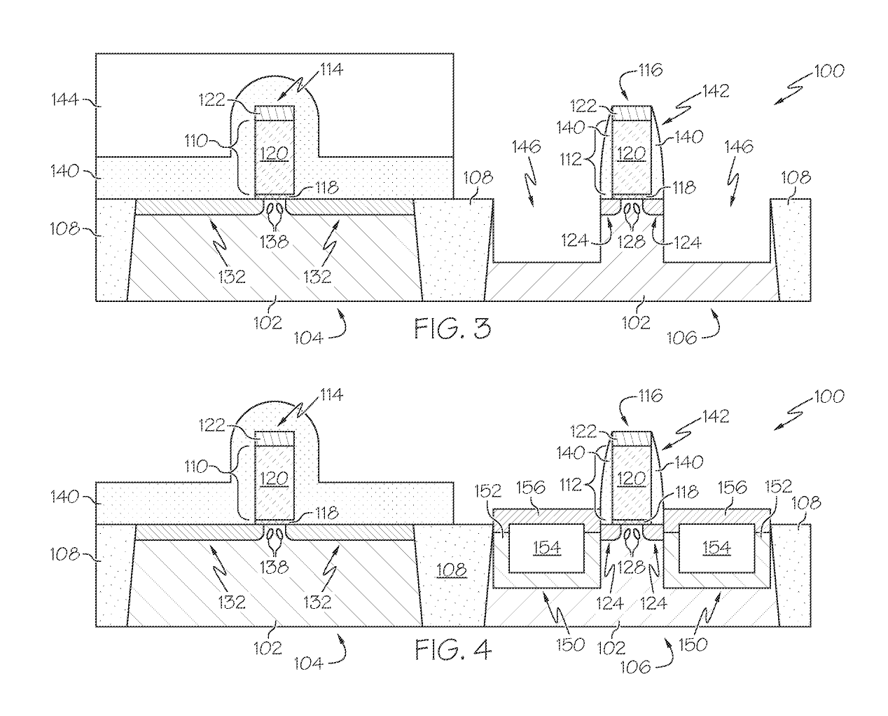

Referring now to FIGS. 3-4, in an exemplary embodiment, fabrication of the semiconductor device structure 100 continues by forming P-type epitaxially-grown stressor regions 150 in the PMOS transistor region 106. In this regard, the fabrication process continues by forming a spacer 142 about sidewalls of the gate structure 112, forming recesses (or cavities) 146 in exposed portions of the PMOS transistor region 106, and epitaxially growing one or more layers of a stress-inducing semiconductor material 152, 154 in the recesses 146. As described in greater detail below, the P-type epitaxially-grown stressor regions 150 are in-situ doped to provide the source and drain regions for the PMOS transistor structure formed on the PMOS transistor region 106, and by virtue of the diffusionless annealing process steps described herein, the dopant profile of the deep source/drain regions for the PMOS transistor is substantially identical to the shape and/or geometric profile of the epitaxial stressor regions 150 (or to put it another way, the dopant profile of the deep source/drain regions corresponds to the shape and/or geometric profile of the recesses).

As illustrated in FIG. 3, to form spacer 142, a layer of insulating material 140, such as silicon nitride or another nitride material, is conformably deposited overlying the semiconductor device structure 100 of FIG. 2 to cover the transistor regions 104, 106. After depositing the nitride material 140, a masking material 144, such as a photoresist material, is formed overlying the NMOS transistor region 104 and the exposed portions of the nitride material 140 overlying the PMOS transistor region 106 are selectively removed by anisotropically etching (e.g., using plasma-based reactive ion etching (RIE)) to form the spacer 142 from the nitride material 140 about the sidewalls of the gate structure 112.

Still referring to FIG. 3, in the illustrated embodiment, the recesses 146 are formed by anisotropically etching the exposed portions of PMOS transistor region 106 using the spacer 142, the gate cap 116, and the field oxide 108 as an etch mask. In this manner, the recesses 146 are vertically aligned with the spacer 142, that is, the interior sidewall surfaces of the recesses 146 adjacent to the remaining source/drain extension regions 124 are naturally formed such that they are aligned with the outward facing surfaces of the spacer 142 at the base of the spacer 142 (e.g., as illustrated in FIG. 3, it appears as though the vertical sidewalls of spacer 142 continue downward to form the corresponding interior sidewall surfaces of the recesses 146 that are proximate the gate structure 112 and/or the channel region). In this manner, the portions of the source/drain extension regions 124 underlying the spacer 142 and/or gate structure 112 remain intact after the recesses 146 are formed. The recesses 146 may be formed by anisotropically etching the exposed silicon material 102 using plasma-based RIE, using commonly known etchant chemistries such as, for example, Cl₂+HBr, HBr+O₂, or Cl₂+HBr+O₂, which have the advantage of etching silicon with good selectivity to the nitride material 140 of the spacer 142 as well as the oxide materials 108, 122. In an exemplary embodiment, the recesses 146 are formed having a depth relative to the surface of the silicon material 102 that is less than the thickness of the silicon material 102 and within the range of about 50 nm to about 60 nm. However, it will be appreciated that the depth of the recesses relative to the surface of the silicon material will vary depending on the needs of a particular embodiment, and the subject matter described herein is not intended to be limited to any particular depth for the recesses. Further, it should be noted that although FIG. 3 depicts substantially U-shaped recess having substantially vertically aligned sidewalls, in accordance with one or more alternative embodiments, a wet anisotropic etch using tetramethylammonium hydroxide (TMAH) or another anisotropic etchant may be performed after an initial plasma-based RIE to form Σ-shaped recesses or recesses having other cross-sectional shapes.

Referring to FIG. 4, after forming recesses 146, any remaining masking material 144 is removed and the epitaxial stressor regions 150 are formed by epitaxially growing one or more layers of compressive stress-inducing semiconductor material 152, 154 having a larger lattice constant than the silicon material 102, such as a silicon germanium material, in the recesses 146 to apply a compressive longitudinal stress to the channel region and thereby increase the mobility of holes in the channel region underlying the gate structure 112. The compressive stress-inducing semiconductor material 152, 154 is in-situ doped with P-type impurity doping elements during the epitaxial growth process steps to provide deep source and drain regions for the PMOS transistor structure formed on the PMOS transistor region 106, as described in greater detail below.

In the illustrated embodiment, a first layer of silicon germanium material 152 is epitaxially grown on the exposed surfaces of the silicon material 102 in the recesses 146 by the reduction of silane (SiH₄), disilane (Si₂H₆), dichlorosilane (SiH₂Cl₂), or another suitable silicon-comprising material in the presence of a suitable germanium-comprising material, and may be grown at a temperature between about 600° C. to about 800° C. The epitaxial growth of the silicon germanium material 154 is selective, and therefore, the silicon germanium material 152 grows only on the exposed surfaces of the substrate silicon material 102 without growing on the exposed surfaces of the field oxide 108 or gate cap 116. In an exemplary embodiment, the silicon germanium material 152 is in-situ doped by adding P-type impurity-doping elements, such as boron ions, to the reactants used to epitaxially grow the silicon germanium. In an exemplary embodiment, the first layer of silicon germanium material 152 has a thickness in the range of about 15 nm to about 20 nm, a germanium concentration of about twenty percent germanium or less, and a peak dopant concentration of about 1×10¹⁹/cm³ to about 5×10¹⁹/cm³.

After the first layer of silicon germanium material 152 is grown on the exposed surfaces of the recesses 146, a second layer of silicon germanium material 154 is formed in the recesses 146 overlying the first layer of silicon germanium material 152. In an exemplary embodiment, the second layer of silicon germanium material 154 has a higher germanium concentration and higher dopant concentration than the first layer of silicon germanium material 152. For example, in accordance with one or more embodiments, the second layer of silicon germanium material 154 has a germanium concentration in the range of about twenty percent germanium to about fifty percent germanium, and preferably around thirty-five percent germanium, and a peak dopant concentration/sheet resistivity of about 2×10²⁰/cm³ to about 5×10²⁰/cm³. As set forth above with respect to the first layer of silicon germanium material 152, the second layer of silicon germanium material 154 is selectively epitaxially grown on the exposed surfaces of the silicon germanium material 152 in the recesses 146 by the reduction of silane (SiH₄), disilane (Si₂H₆), dichlorosilane (SiH₂Cl₂), or another suitable silicon-comprising material in the presence of a germanium-comprising material at a temperature between about 600° C. to about 800° C., and the silicon germanium material 154 is in-situ doped by adding P-type impurity-doping elements, such as boron ions, to the reactants. In an exemplary embodiment, the second layer of silicon germanium material 154 has a thickness in the range of about 20 nm to about 40 nm, and preferably around 30 nm.

Still referring to FIG. 4, in an exemplary embodiment, after epitaxially growing the compressive stress-inducing semiconductor material 152, 154 in the recesses 146, the fabrication process continues by forming a silicon material 156 in the recesses 146 overlying the stress-inducing semiconductor material 152, 154. In an exemplary embodiment, a monocrystalline silicon material 156 is selectively epitaxially grown on exposed surfaces of the stress-inducing semiconductor material 152, 154 by the reduction of dichlorosilane (SiH₂Cl₂) or another suitable silicon-comprising material, and the silicon material 156 may be grown at a temperature of about 720° C. The silicon material 156 is in-situ doped by adding P-type impurity-doping elements, such as boron ions, to the reactants used to epitaxially grow the silicon, and in exemplary embodiments, the silicon material 156 has a peak dopant concentration of about 2×10²⁰/cm³ to about 5×10²⁰/cm³. Thus, the in-situ doped epitaxially grown materials 152, 154, 156 and the source/drain extensions 124 collectively provide the source and drain regions for the PMOS transistor structure formed on the PMOS transistor region 106.

In an exemplary embodiment, the silicon material 156 is grown to a thickness of about 10 nm. As illustrated, the combined thickness of the materials 152, 154, 156 in the recesses 146 is greater than or equal to the depth of the recesses 146 (e.g., a “flush” fill or slight overfill) to ensure that the recesses 146 are filled to a minimum height that meets or exceeds the surface of the substrate silicon material 102 underlying the gate structure 112. In an exemplary embodiment, the epitaxially-grown silicon material 156 and the substrate silicon material 102 are the same type of material, such that they exhibit substantially the same chemical properties (e.g., etch rates, oxidation rates, and the like). As illustrated in FIG. 4, the stressor regions 150 are encapsulated or otherwise covered by the epitaxially-grown silicon material 156, such that the surfaces of the stressor regions 150 are not exposed. Accordingly, any subsequent process steps configured for use with silicon material 102 do not need to be modified to account for the presence of the stressor regions 150 because the stressor regions 150 are not exposed.

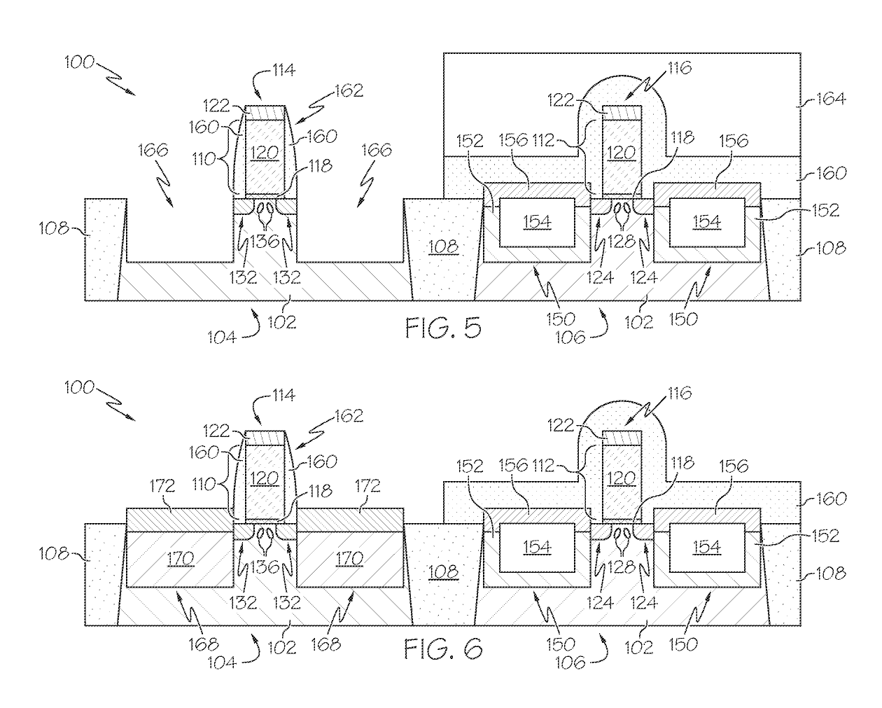

Referring now to FIGS. 5-6, in an exemplary embodiment, after forming the P-type stressor regions 150, fabrication of the semiconductor device structure 100 continues by forming N-type epitaxial stressor regions 168 in the NMOS transistor region 104 prior to activating the dopant ions of the in-situ doped epitaxially-grown materials 152, 154, 156. In an exemplary embodiment, the nitride material 140 is removed by performing a hot phosphoric acid (H₃PO₄) etching process (which may also partially reduce the thickness of the oxide gate cap 116), and after the nitride material 140 is removed, the fabrication process continues by forming a spacer 162 about sidewalls of the gate structure 110 in a similar manner as descried above in the context of FIG. 3. In this regard, a layer of insulating material 160, such as silicon nitride or another nitride material, is conformably deposited to cover the transistor regions 104, 106, and after depositing the nitride material 160, a masking material 164 is formed overlying the PMOS transistor region 106 and the exposed portions of the nitride material 160 overlying the NMOS transistor region 104 are selectively removed by anisotropic etching to form the spacer 162 from the nitride material 160. After forming the spacer 152, recesses 166 are formed by anisotropically etching the exposed portions of NMOS transistor region 104 using the spacer 162, the oxide gate cap 114, and the field oxide 108 as an etch mask in a similar manner as set forth above with respect to recesses 146. In this regard, the depth and shape of the recesses 166 may be substantially the same as recesses 146.

Referring now to FIG. 6, after forming recesses 166, any remaining masking material 164 is removed and the epitaxial stressor regions 168 are formed by epitaxially growing a tensile stress-inducing semiconductor material 170 having a smaller lattice constant than the silicon material 102 in the recesses 166 to apply a tensile longitudinal stress to the channel region and thereby increase the mobility of electrons in the channel region underlying the gate structure 110. For example, a layer of silicon carbon material 170 may be epitaxially grown on the exposed surfaces of the silicon material 102 in the recesses 166 by the reduction of silane (SiH₄), disilane (Si₂H₆), dichlorosilane (SiH₂Cl₂), or another suitable silicon-comprising material in the presence of methane (CH₄), ethane (C₂H₆), or another suitable carbon-comprising material, and the silicon carbon material 170 may be grown at a temperature between about 600° C. to about 800° C. In an exemplary embodiment, silicon carbon material 170 includes about two percent carbon. The silicon carbon material 170 is in-situ doped by adding N-type impurity-doping elements, such as phosphorous ions, to the reactants used to epitaxially grow the silicon carbon. In an exemplary embodiment, the layer of silicon carbon material 170 has a peak dopant concentration in the range of about 5×10²⁰/cm³ to about 1×10²¹/cm³.

Still referring to FIG. 6, in an exemplary embodiment, after epitaxially growing the in-situ doped silicon carbon material 170 in the recesses 166, the fabrication process continues by forming a silicon material 172 in the recesses 166 overlying the silicon carbon material 170. In a similar manner as set forth above, in exemplary embodiments, a monocrystalline silicon material 172 is selectively epitaxially grown on exposed surfaces of the silicon carbon material 170, and the silicon material 172 is in-situ doped by adding N-type impurity-doping elements, such as phosphorous ions, to the reactants used to epitaxially grow the silicon. In exemplary embodiments, the silicon material 172 has a peak dopant concentration in the range of about 5×10²⁰/cm³ to about 1×10²¹/cm³ and a thickness of about 10 nm. As described above, the thickness of the silicon material 170 is such that the combined thickness of the epitaxially-grown materials 170, 172 in the recesses 166 is greater than or equal to the depth of the recesses 166 (e.g., a “flush” fill or slight overfill) to ensure that the recesses 166 are filled to a minimum height that meets or exceeds the surface of the substrate silicon material 102 underlying the gate structure 110.

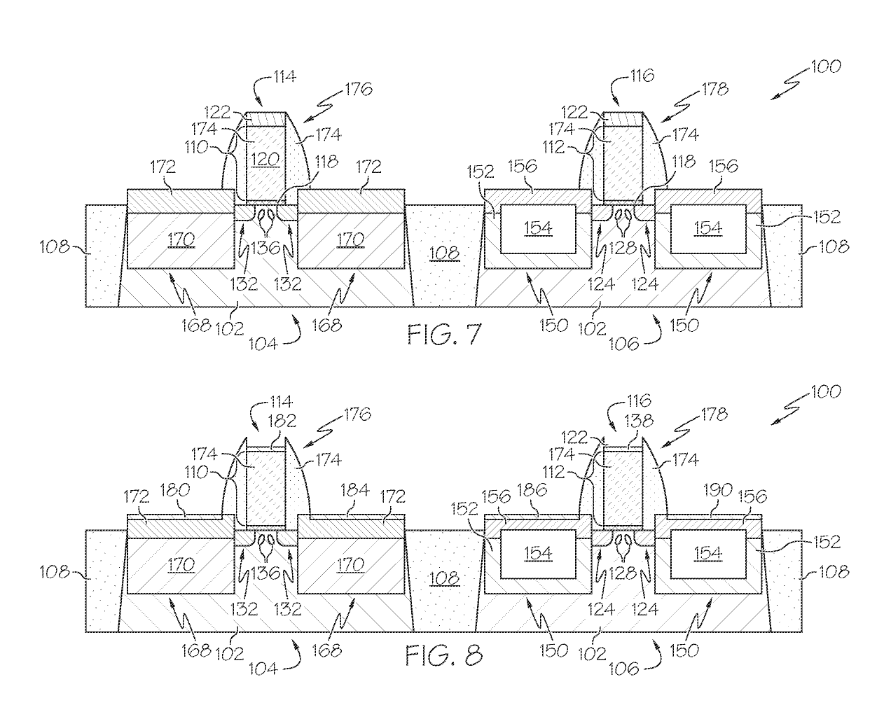

Referring now to FIG. 7, in an exemplary embodiment, fabrication of the semiconductor device structure 100 continues by removing the nitride material 160 and forming offset spacers 176, 178 about sidewalls of the gate structures 110, 112. In a similar manner as described above, the nitride material 160 is removed by performing a hot phosphoric acid etching process. After removing the nitride material 160, the sidewall spacers 176, 178 are formed by conformably depositing a layer of insulating material 174, such a nitride material, overlying the transistor regions 104, 106 and anisotropically etching the insulating material 174 to selectively remove portions of the insulating material 174 overlying the gate structures 110, 112 and form spacers 176, 178 from the nitride material 174.

In an exemplary embodiment, after forming the spacers 176, 178, a second diffusionless annealing (or ultrafast annealing (UFA)) is performed to concurrently activate the dopant ions in the in-situ doped epitaxially grown materials 152, 154, 156, 170, 172. As described above, the semiconductor device structure 100 of FIG. 7 is heated by performing a flash anneal or a laser anneal for an amount of time that is less than a threshold amount of time that would otherwise result in the diffusion of the dopant ions in the epitaxially-grown materials 152, 154, 156, 170, 172, source/drain extensions 124, 132 and/or halo regions 128, 136. In an exemplary embodiment, the semiconductor device structure 100 is heated to a temperature of about 1200° C. or more for about 10 milliseconds or less to inhibit or otherwise ensure that dopant ions in the epitaxially-grown materials 152, 154, 156, 170, 172, source/drain extensions 124, 132 and/or halo regions 128, 136 do not diffuse. In this regard, the relatively high temperature of the diffusionless anneal may activate the dopant ions of the epitaxially-grown materials 152, 154, 156, 170, 172, source/drain extensions 124, 132 and/or halo regions 128, 136 but the duration of the diffusionless anneal is such that any lateral diffusion of the dopant ions is inhibited, prevented, or is otherwise negligible.

Referring now to FIG. 8, in an exemplary embodiment, after activating the dopant ions in epitaxially-grown materials 152, 154, 156, 170, 172, fabrication of the semiconductor device structure 100 continues by removing the oxide gate caps 114, 116 and forming contact regions 180, 182, 184, 186, 188, 190 on the exposed surfaces of the silicon material 156, 172 and gate electrode material 120. In an exemplary embodiment, a diluted hydrofluoric acid etching process or another known etching process is performed to remove the oxide material 122 until the upper surfaces of the gate electrode material 120 are exposed. After removing the oxide gate caps 114, 116, the contact regions 180, 182, 184, 186, 188, 190 are formed by conformably depositing a layer of silicide-forming metal onto the surfaces of the silicon material 156, 172 and gate electrode material 120. In an exemplary embodiment, the silicide-forming metal is realized as nickel plus about five percent platinum. In this regard, by virtue of the reduced contact resistance of the in-situ doped silicon material 156, 172, the platinum concentration may be reduced (e.g., relative to conventional silicidation processes where the platinum concentration is about ten percent). It should be noted that in other embodiments, other silicide-forming metals may be utilized in lieu of nickel platinum, such as, for example, cobalt, nickel, rhenium, ruthenium, or palladium, or alloys thereof. In an exemplary embodiment, the silicide-forming metal is deposited (e.g., by sputtering) to a thickness in the range of about 8 nm to about 12 nm. After forming the silicide-forming metal layer, the semiconductor device structure 100 is heated, for example, by performing a rapid thermal anneal (RTA) for about sixty second at 260° C. to cause the silicide-forming metal to react with exposed silicon and form the metal silicide contact regions 180, 182, 184, 186, 188, 190 at the top of each of the source and drain regions (e.g., on the silicon material 156, 172) as well as on top of the gate structures 110, 112. In this regard, the temperature and duration of the anneal is such that diffusion of dopant ions in the epitaxially-grown materials 152, 154, 156, 170, 172, source/drain extensions 124, 132 and/or halo regions 128, 136 is inhibited, prevented, or is otherwise negligible.

Still referring to FIG. 8, in an exemplary embodiment, by virtue of the in-situ doped epitaxial silicon material 156, 172 overlying the epitaxial stressor regions 150, 168, the silicide contact regions 180, 184, 186, 190 that overlie the epitaxial stressor regions 150, 168 may include dopant ions (or concentrations thereof) corresponding to the doping of the silicon material 156, 172 but do not include any stress-inducing material. In other words, silicide contact regions 180, 184 do not include any carbon atoms and silicide contact regions 186, 190 do not include any germanium atoms. Any silicide-forming metal that is not in contact with exposed silicon (e.g., any silicide-forming metal deposited on the spacers 176, 178 or field oxide 108) does not react during the annealing to form a silicide and may subsequently be removed in a conventional manner (e.g., by wet etching in a H₂O₂/H₂SO₄ or HNO₃/HCl solution). After forming the silicide contact regions 180, 182, 184, 186, 188, 190, fabrication of the semiconductor device structure 100 may be completed using well known final process steps (e.g., back end of line (BEOL) process steps), which will not be described in detail herein.

To briefly summarize, one advantage of the semiconductor device structure 100 and fabrication methods described herein is that by virtue of the in-situ doping and diffusionless annealing process steps described above, the overall thermal budget is reduced, thereby allowing the epitaxial silicon carbon stressor regions to be integrated with epitaxial silicon germanium stressor regions without compromising the material properties (e.g., stress relaxation) of the silicon carbon stressor regions that may otherwise result from ion implantation and/or increased exposure to relatively high temperatures. Additionally, the in-situ doping allows for the dopant concentration of the epitaxial stressor regions to be increased (or alternatively, the sheet resistance decreased) relative to implanted source/drain regions, thereby reducing the resistance of the semiconductor device structure. Furthermore, the in-situ doping allows for greater germanium concentrations within the silicon germanium stressor regions to provide increased strain and/or mobility for the channel regions of the PMOS transistor devices. The absence of diffusion also reduces variations across the wafer that would otherwise result from variations in diffusion rates across the wafer. Additionally, as noted above, the reduction of the platinum content in the nickel platinum may also reduce material costs.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A method of fabricating a semiconductor device structure on a semiconductor substrate including a first region of semiconductor material and a second region of semiconductor material, the method comprising:
forming first doped stressor regions in the first region of semiconductor material;
forming second doped stressor regions in the second region of semiconductor material after forming the first doped stressor regions; and
after forming the second doped stressor regions, annealing the semiconductor device structure for a first amount of time to activate ions of the first and second doped stressor regions concurrently, wherein the first amount of time is chosen to inhibit diffusion of the ions of the first and second doped stressor regions.

2. The method of claim 1, wherein the second doped stressor regions are formed prior to activating the ions of the first doped stressor regions.

3. The method of claim 1, wherein the first amount of time is ten milliseconds or less.

4. The method of claim 3, wherein annealing the semiconductor device structure comprises heating the semiconductor device structure to a temperature greater than or equal to 1200° for the first amount of time.

5. The method of claim 1, wherein:
forming the first doped stressor regions comprises:
forming first recesses in the first region about a first gate structure overlying the first region; and
epitaxially growing a first in-situ doped stress-inducing semiconductor material in the first recesses; and
forming the second doped stressor regions comprises:
forming second recesses in the second region about a second gate structure overlying the second region; and
epitaxially growing a second in-situ doped stress-inducing semiconductor material in the second recesses.

6. The method of claim 5, further comprising:
epitaxially growing a first in-situ doped silicon material in the first recesses overlying the first in-situ doped stress-inducing semiconductor material; and
epitaxially growing a second in-situ doped silicon material in the second recesses overlying the second in-situ doped stress-inducing semiconductor material.

7. The method of claim 6, wherein the first in-situ doped silicon material is epitaxially grown prior to forming the second doped stressor regions.

8. The method of claim 5, wherein epitaxially growing the first in-situ doped stress-inducing semiconductor material in the first recesses comprises:
epitaxially growing a first layer of silicon germanium material in the first recesses, the first layer having a first germanium concentration; and
epitaxially growing a second layer of silicon germanium material overlying the first layer, the second layer having a second germanium concentration greater than the first germanium concentration.

9. The method of claim 5, wherein epitaxially growing the first in-situ doped stress-inducing semiconductor material in the first recesses comprises:
epitaxially growing a first layer of silicon germanium material in the first recesses, the first layer having a first dopant concentration; and
epitaxially growing a second layer of silicon germanium material overlying the first layer, the second layer having a second dopant concentration greater than the first dopant concentration.

10. The method of claim 1, further comprising:
prior to forming the first and second doped stressor regions:
forming first extension regions in the first region about a first gate structure overlying the first region;
forming second extension regions in the second region about a second gate structure overlying the second region; and
annealing the semiconductor device structure for a second amount of time after forming the first and second extension regions, wherein the second amount of time is chosen to inhibit diffusion of the first and second extension regions.

11. The method of claim 1, further comprising forming oxide gate caps overlying a first gate structure and a second gate structure prior to forming the first and second doped stressor regions, the first gate structure overlying the first region and the second gate structure overlying the second region.

12. A method of fabricating a semiconductor device structure on a semiconductor substrate including a first region of semiconductor material and a second region of semiconductor material, the method comprising:
epitaxially growing in-situ doped silicon germanium regions in the first region of semiconductor material;
epitaxially growing in-situ doped silicon carbon regions in the second region of semiconductor material prior to activating ions of the silicon germanium regions; and
performing a diffusionless anneal to concurrently activate ions in the silicon carbon regions and the ions in the silicon germanium regions.

13. The method of claim 12, wherein performing the diffusionless anneal comprises heating the semiconductor device structure to a temperature greater than or equal to 1200° for an amount of time less than or equal to ten milliseconds.

14. The method of claim 13, wherein heating the semiconductor device comprises performing a flash anneal or a laser anneal.

15. The method of claim 12, further comprising:
forming extension regions in the first and second regions prior to epitaxially growing the silicon germanium regions; and
performing a second diffusionless anneal after forming the extension regions and prior to epitaxially growing the silicon germanium regions.

16. The method of claim 12, further comprising:
epitaxially growing a first in-situ doped silicon material overlying the silicon germanium regions prior to epitaxially growing the silicon carbon regions; and
epitaxially growing a second in-situ doped silicon material overlying the silicon carbon regions prior to performing the diffusionless anneal.

17. The method of claim 16, further comprising forming silicide contact regions in the first and second in-situ doped silicon material.

18. The method of claim 12, wherein epitaxially growing the silicon germanium regions comprises:
forming recesses in the first region;
epitaxially growing a first layer of silicon germanium material in the recesses, the first layer having a first germanium concentration; and
epitaxially growing a second layer of silicon germanium material overlying the first layer, the second layer having a second germanium concentration greater than the first germanium concentration.

19. The method of claim 12, wherein epitaxially growing the silicon germanium regions comprises:
forming recesses in the first region;
epitaxially growing a first layer of silicon germanium material in the recesses, the first layer having a first dopant concentration; and
epitaxially growing a second layer of silicon germanium material overlying the first layer, the second layer having a second dopant concentration greater than the first dopant concentration.

20. A semiconductor device comprising:
a semiconductor material;
a gate structure overlying the semiconductor material;
in-situ doped stressor regions formed in the semiconductor material about the gate structure; and
in-situ doped silicon material overlying the in-situ doped stressor regions.
